(19) United States
(12) Patent Application Publication
(10) Pub. No.: US 2025/0300067 A1
(43) Pub. Date: Sep. 25, 2025

(54) INTEGRATED CIRCUIT CHIP HAVING VIA TOWERS FOR POWER CONNECTION AND METHOD OF FORMING THE SAME

(71) Applicant: TAIWAN SEMICONDUCTOR MANUFACTURING COMPANY, LTD., Hsinchu (TW)

(72) Inventors: Chia Chen LEE, Taipei City (TW); Chia-Tien WU, Taichung City (TW); Chih-Chao CHOU, Hsinchu City (TW); Wei-Chen CHU, Taichung City (TW); Ching-Wei TSAI, Hsinchu City (TW)

(21) Appl. No.: 18/611,797

(22) Filed: Mar. 21, 2024

(51) Int. Cl. H01L 23/522; H01L 21/768; H01L 23/00; H01L 23/528; H01L 23/532; H01L 25/065; H01L 27/06

(52) U.S. Cl. CPC H01L 23/5226; H01L 21/76802; H01L 21/76877; H01L 23/528; H01L 23/5283; H01L 23/5286; H01L 23/53295; H01L 24/08; H01L 25/0657; H10D 88/00; H01L 2224/08145; H01L 2225/06541; H01L 2924/381

(57) ABSTRACT

Embodiments of the present disclosure provide integrated circuit chips including via towers formed with stacks of conductive layers formed during fabrication of semiconductor devices and interconnect structures of the integrated circuit chips. The via towers may be connected to provide electrical power to subsequently stacked integrated circuit chips. The via towers according to the present disclosure reduce cost of fabrication because the via towers are fabricated without additional processing sequences. The via towers may be integrated in the circuit layout to form a low resistance power rail, therefore, improving performance.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, in multi-chip modules, or in other types of packaging, for example.

Three-dimensional integrated circuits (3DICs) are a relatively recent development in semiconductor packaging in which multiple semiconductor dies are stacked upon one another, such as package-on-package (PoP) and system-in-package (SiP) packaging techniques. A 3DIC includes a semiconductor device with two or more layers of active electronic components integrated, e.g., vertically stacked and connected, to form an integrated circuit. 3DIC technologies include die-on-die stacking, die-on-wafer stacking, and wafer-on-wafer stacking. 3DIC systems may provide improved integration density and other advantages, such as faster speeds and higher bandwidth, because of the decreased length of interconnects between the stacked dies, as examples. However, 3DIC systems may exhibit high IR drops, e.g., voltage drops, compared to their two-dimensional counterparts. Increased IR drops in 3DIC systems can lead to increased power consumption and degraded device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematical cross-sectional view of a 3DIC structure according to embodiments of the present disclosure.

FIG. 2A is a schematical cross-sectional view of a via tower in an integrated circuit chip according to embodiments of the present disclosure.

FIG. 2B is a schematic top view of the via tower of FIG. 2A.

FIG. 2C is a schematical partial cross-sectional view of the via tower showing details of the material layers of the via tower of FIG. 2A.

FIG. 3A is a schematical cross-sectional view of a via tower in an integrated circuit chip according to embodiments of the present disclosure.

FIG. 3B is a schematic top view of the via tower of FIG. 3A.

FIG. 4 is a schematical cross-sectional view of a via tower in an integrated circuit chip according to embodiments of the present disclosure.

FIG. 5 is a schematical cross-sectional view of a via tower in an integrated circuit chip according to embodiments of the present disclosure.

FIG. 6A is a schematical cross-sectional view of a via tower in an integrated circuit chip according to embodiments of the present disclosure.

FIG. 6B is a schematic top view of the via tower of FIG. 6A.

FIG. 6C is a schematical partial cross-sectional view of the via tower showing details of the material layers of the via tower of FIG. 6A.

FIG. 7 is a flow diagram of forming of integrated circuit chips according to embodiments of the present disclosure.

FIGS. 8A-8F schematically demonstrate various processing stages during fabrication of integrated circuit chip according to embodiments of the present disclosure.

FIGS. 9A-9E schematically demonstrate various processing stages during fabrication of dummy dies according to embodiments of the present disclosure.

FIG. 10 a schematical cross-sectional view of a 3DIC structure according to embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will be described with respect to embodiments in a specific context, namely an integrated circuit package. Other embodiments may also be applied, however, to other electrically connected components, including, but not limited to, package-on-package assemblies, die-to-die assemblies, wafer-to-wafer assemblies, die-to-substrate assemblies, die-to-wafer assemblies, in assembling packaging, in processing substrates, interposers, or the like, or mounting input components, boards, dies or other components, or for connection packaging or mounting combinations of any type of integrated circuit or electrical component. Various embodiments described herein allow for packaging functional components (such as, for example, integrated circuit dies) of varying functionalities and dimensions (such as, for example, heights) in a same integrated circuit package. Various embodiments described herein may be integrated into a chip-on-wafer-on-substrate (CoWoS) process and a chip-on-chip-on-substrate (CoCoS) process.

An IC structure can include a compilation of layers with different functionality, such as interconnects, power distribution network, logic chips, memory chips, radio frequency (RF) chips, and the like. By way of example and not limitation, the logic chips can include central process units (CPUs) and the memory chips can include static access memory (SRAM) arrays, dynamic random-access memory (DRAM) arrays, magnetic random-access memory (MRAM) arrays, other types of memory arrays, or combinations thereof. A 3DIC structure is a non-monolithic vertical structure developed based on the IC structure and can include, for example, two to eight two-dimensional 2D flip chips stacked on top of each other through various bonding techniques, such as hybrid bonding.

In IC and 3DIC structures, each of the layers can be interconnected by micro-bumps, through silicon vias (TSVs), hybrid bonding, other types of interconnect structures, or combinations thereof. IC structures are powered by power wire grids including power lines and ground lines. Power wire grids can be electrically connected to one end of the IC package and supply power to each layer through conductive structures, such as power grid pillars formed by TSVs. However, as more layers are stacked on top of each other, increased layers of TSVs and interconnect structures in IC structures can lead to increased resistances and IR drops (e.g., greater than 5% voltage drop). In addition, TSVs used to deliver power to device layers through interconnect layers can occupy valuable routing space for signal lines, increase the resistance of interconnects and TSVs, deteriorate the performance of the chips, and reduce the lifetime of the IC structures.

The present disclosure provides a new design for die-to-die connection with improved cost-efficiency and performance. With the existence of back-side (B/S) process, power delivery in SoIC structures can be achieved using via towers. The via towers may be formed during the same processes with B/S interconnect structure, and/or frontside interconnect structures, therefore, omitting the extra TSV process. The via towers according to the present disclosure include conductive plates and vias. The conductive plates and vias may have a large size and/or be of a large number, thus, forming low resistance power rail. The fabrication of the via towers in integrated in the existing processes, therefore, is cost-effective. Accordingly, the via towers according to the present disclosure provide low resistance power rail connection from a back side of the bottom die through the whole chip of the bottom die to the top-die and others.

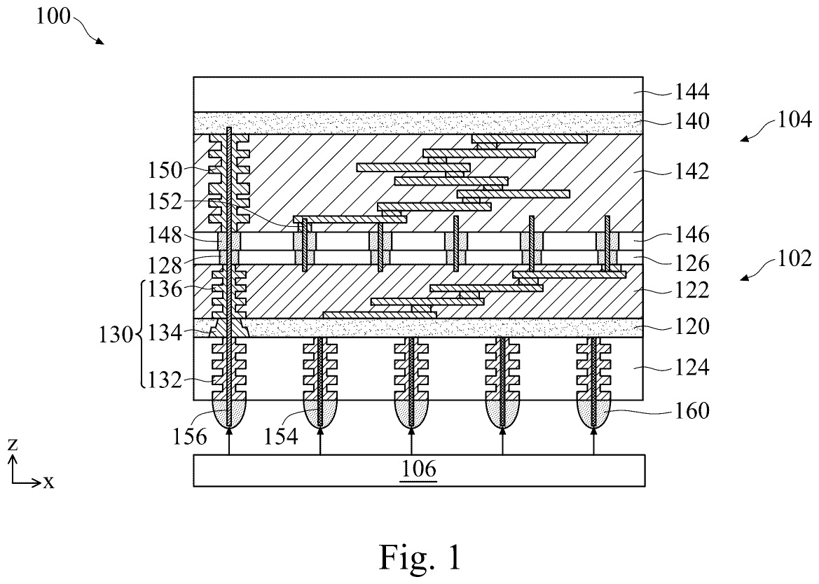

FIG. 1 is a schematical cross-sectional view of a 3DIC structure 100 according to embodiments of the present disclosure. The 3DIC structure 100 includes two chip layers, a bottom chip layer 102 and a top chip layer 104. It should be noted that the number of chip layers is not limiting. Additional chip layers may be added according to system design.

The top chip layer 104 and the bottom chip layer 102 are vertically bonded together to form the 3DIC structure 100. Other structures, such as micro-bumps, molding regions, dummy regions, adhesion layers, a heat sink, interconnects, ball grid array (BGA) connectors, silicon interposers, and other components or structural elements may be included. In some embodiments, the 3DIC structure 100 may include peripheral structures, not shown, to provide mechanical support and/or provide thermal conduction for heat dissipation. By way of example and not limitation, the top chip layer 104 may include one or more microprocessors or CPUs, while the bottom chip layer 102 may include one or more memory chips, such as SRAM chips, DRAM chips, MRAM chips, other types of memory chips, or combinations thereof.

The top chip layer 104 may include one or more device layer 140 formed on and over a semiconductor substrate 144 and an interconnect structure 142 disposed on the device layer 140. The interconnect structure 142 include conductive lines and vias formed in a dielectric layer. The conductive lines and vias form communication paths and power supply paths to semiconductor devices in the device layer 140.

The bottom chip layer 102 may include one or more device layer 120, a first interconnect structure 122 disposed on a first side of the device layer 120, and a second interconnect structure 124 disposed on a second side of the device layer 120. In some embodiments, the first interconnect structure 122 is formed on the front side of the device layer 120 with conductive lines and vias forming communication paths for semiconductor devices in the device layer 120. The second interconnect structure 124 is formed on the backside of the device layer 120. The second interconnect structure 124 may include a backside power network configured to supply power to the semiconductor device in the device layer 120.

The top chip layer 104 and the bottom chip layer 102 are vertically stacked and bonded together with the interconnect structures 142 and 122 facing each other. The top chip layer 104 and the bottom chip layer 102 may be bonded using suitable bonding technologies, such as hybrid bonding, fusion bonding, anodic bonding, direct bonding, room temperature bonding, pressure bonding, and/or combinations thereof. In the example shown in FIG. 1, the top chip layer 104 and the bottom chip layer 102 are bonded together by bonding films 126, 146. In some embodiments, bond pad features 128 are formed in the bonding film 126 and at least a portion of the bond pad features 128 in connection with conductive features in the interconnect structure 122 of the bottom chip layer 102. Bond pad features 148 are disposed in the bonding film 146 and at least a portion of the bond pad features 148 are connected to the conductive features in the interconnect structure 142 of the top chip layer 104. In some embodiments, some or all of the bond pad features 128 and the bond pad features 148 are aligned and bonded together communication between the top chip layer 104 and the bottom chip layer 102. Each pair of bond pad features 128, 148 form an inter-chip communication path 152. As discussed below, the inter-chip communication paths 152 formed by the bond pad features 148, 128 may create inter-chip communication for signal or power supply.

According to embodiments of the present disclosure, one or more via towers may be formed through a chip layer to provide electric power to other chip layers in a vertical chip stack or a 3DIC. In the example of FIG. 1, one or more via towers 130 are formed in the bottom chip layer 102 operable to connect a power supply to the top chip layer 104. In some embodiments, a power supply 106 is configured to electrically connected to the top chip layer 104 through the via towers 130 in the bottom chip layer 102.

The number and distribution of the via towers 130 may vary according to the circuit design. In some embodiments, the via towers 130 may be disposed in a seal ring region of dies in the bottom chip layer 102. In other embodiments, the via towers 130 may be distributed among semiconductor devices in the bottom chip layer 102. In some embodiments, the bottom chip layer 102 may include one via tower 130 to the power supply 106 to the top chip layer 104. The conductive plates and vias in the via tower 130 may have relatively large cross section areas in x-y planes, therefore, to achieve low resistance. In other embodiments, the bottom chip layer 102 may include two or more via towers 130. In some embodiments, the two or more via towers 130 may be parallelly connected between the same power supply and chip layer(s) with reduced IR drop because the two or more via towers 130 cumulatively form a large cross-sectional area for current flow.

The via towers 130 are formed with vertically stacked conductive plates and vias formed in dielectric layers in the device layer 120 and the interconnect structures 122, 124. Each of the via towers 130 includes alternative layers of conductive plates and vias stacked together. The fabrication of the conductive plates and vias are integrated with the fabrication of the device layer 120, and the interconnect structures 122, 124. The conductive plates and vias of the via tower 130 may be Cu, Ru, W, Ti, Al, Co, Mo, Ir, Rh, C, Ni, Sc, Nb, Ta, Si, or a combination thereof. Materials of the conductive plates and vias may vary at different levels according to the process flow. For example, some portions of the via tower 130 may be formed from copper plates and vias, and other portions of the via tower may include tungsten or aluminum.

As shown in FIG. 1, the via tower 130 includes a backside stack 132 disposed in the backside interconnect structure 124, a middle stack 134 disposed in the device layer 120, and the front side stack 136 disposed in the front side interconnect structure 122. the backside stack 132, the middle stack 134, and the front side stack 136 are stacked vertically forming a conductive column through the bottom chip layer 102 allowing electric communication.

The backside stack 132 includes plates and vias formed in layers of dielectric materials of the backside interconnect structure 124. The front side stack 136 includes plates and vias formed in layers of dielectric materials of the front side interconnect structure 122. In some embodiments, materials of the front side stack 136 and backside stack 132 includes the same material in the interconnect structures, such as copper.

The middle stack 134 may include one or more layers of conductive plates and/or vias formed through the device layer 120. In some embodiments, the middle stack 134 includes conductive plates and vias formed during formation of source/drain contacts and gate contacts. Conductive material for the middle stack 134 may be the same as source/drain contacts and gate contacts, such as tungsten. In other embodiments, the middle stack 134 may include conductive features formed during backside processing. Conductive material for the middle stack 134 may be the same as backside interconnect structures, such as copper.

In some embodiments, the via tower 130 includes both the front side stack 136 and the backside stack 132. In other embodiments, one of the backside stack 132 and front side stack 136 may be omitted, and the via tower 130 may be connected to a power supply via a power delivering network (PDN) formed in the front side or the back side. For example, the via tower 130 may include the front side stack 136 and the middle stack 134 with the backside stack 132 may be omitted, and the via tower 130 is connected to a power supply via a backside PDN, or backside power grail.

During operation, the power supply 106 is connected to the bottom chip layer 102 via bond pads 160. The bond pads 160 are in electrical connection with the via tower 130 and the backside interconnect structure 124. In some embodiments, the power supply 106 is connected to the device layer 120 of the bottom chip layer 102 via flow paths 154, which may include one or more bond pad 160 and conductive features in the backside interconnect structure 124. The power supply 106 is connected to the device layer 140 of the top chip layer 104 via a communication path 156, which may include the bond pad 160, the via tower 130 through the bottom chip layer 102, the bond pad feature 128, the bond pad feature 148, and conductive features in the interconnect structure 142 of the top chip layer 104. In some embodiments, the interconnect structure 142 may include a via tower 150, similar to the front side stack 136 of the via tower 130, formed in the interconnect structure 142.

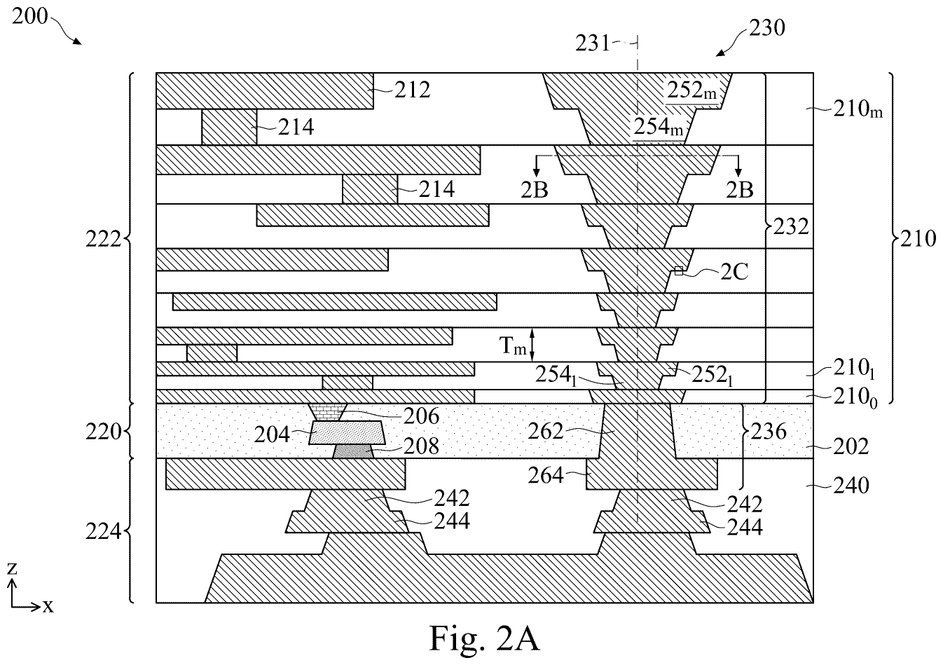

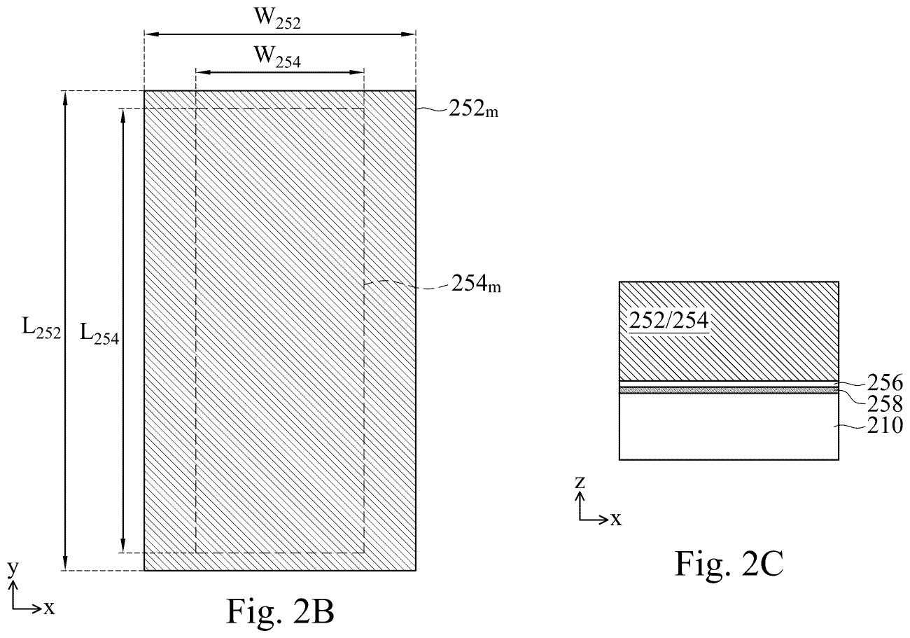

FIG. 2A is a schematical cross-sectional view of an integrated circuit chip 200 according to embodiments of the present disclosure. The integrated circuit chip 200 may be used in a 3DIC package. The integrated circuit chip 200 includes one or more via towers 230 configured to provide power supply to one or more chips vertically stacked with the integrated circuit chip 200. For example, the integrated circuit chip 200 may be used as the bottom chip layer 102 in the 3DIC structure 100 of FIG. 1.

The integrated circuit chip 200 include a device layer 220, a front side interconnect structure 222 disposed on a front side of the device layer 220, and backside power delivering network (PDN) 224 disposed on a backside of the device layer 220. The device layer 220 may include a plurality of semiconductor devices 204 formed on and from a semiconductor substrate. The semiconductor devices 204 may be fabricated on and from a semiconductor substrate by various semiconductor processes, such as depositing, patterning, etching, doping various thin films over the semiconductor substrate. Front side contact features 206 and are formed on and below the semiconductor devices 204 to enable signal communication with the semiconductor devices 204 and to provide signal communication and/or power supply to the semiconductor devices 204. The front side contact features 206 and the back side contact features 208 are disposed in dielectric material 202. The dielectric material 202 may include one or more layers deposited during fabrication.

The semiconductor devices 204 may be transistors, diodes, imaging sensors, resistors, capacitors, inductors, memory cells, combinations thereof, and/or other suitable devices. In some embodiments, the semiconductor devices 204 may be transistors, such as FinFET and nanostructure FET having one or more channels wrapped around by a gate electrode layer. The front side contact features 206 may include source/drain contact features and gate contact features. The back side contact features 208 may include source/drain contact features, and/or gate contact features.

The front side interconnect structure 222 are formed over the device layer 220. The interconnect structure 222 includes an IMD layer 210, which may be multiple ILD layers or intermetal dielectric (IMD) layers 210m. Conductive lines 212 and conductive vias 214 are embedded in the IMD layer 210. The conductive lines 212 and conductive vias 214 form electrical paths to connect with the semiconductor devices 204. The interconnect structure 222 may be formed layer by layer by a metallization process, such as damascene process, to embed layers of conductive lines 212m and conductive vias 214m in corresponding IMD layers 210m. As shown in FIG. 2A, the interconnect structure 222 may include IMD layers 210₀, 210₁, . . . , 210m with conductive lines 212 and conductive vias 214 therein. In some embodiments, the IMD layers 210₀, 210₁, . . . , 210m may have increasing thickness Tₘ with the conductive lines 212 and vias 214 in increasing dimensions. For example, the conductive lines 212 and vias 214 are denser and smaller in sizes in layers closers to the device layer 220 and sparser and larger in layers farther away from the device layer 220. In some embodiments, each of the IMD layer 210₀, 210₁, . . . , 210m has a thickness along the z-axis ranging from about 50 Angstroms to about 500 Angstroms,

The IMD layer 210 may include an insulating material made of an oxygen-containing material, such as silicon oxide or fluorine-doped silicate glass (FSG); a nitrogen-containing material, such as silicon nitride, silicon oxynitride (SiON), SiOCN, SiCN; a low-k dielectric material, e.g., a material having a k value lower than that of silicon oxide; or any suitable dielectric material. In some embodiments, the IMD layer 210 includes silicon oxide. The IMD layer 210 may be formed by chemical vapor deposition (CVD), atomic layer deposition (ALD), spin coating, or other suitable process. The conductive lines 212 and conductive vias 214 may each include an electrically conductive material, such as Cu, Co, Ru, Mo, Cr, W, Mn, Rh, Ir, Ni, Pd, Pt, Ag, Au, Al, alloys thereof, or other suitable material. The conductive lines 212 and conductive vias 214 may be formed by physical vapor deposition (PVD), CVD, ALD, or other suitable process.

The backside PDN 224 include one or more layers of conductive lines 244 and conductive vias 242 formed in one or more layers of backside dielectric layer 240. The conductive lines 244 form power grid wires configured to provide electrical connection between a power supply and the semiconductor devices 204. In some embodiments, the power grid wires can be electrically connected to the same voltage level, such as Vss. e.g., ground voltage reference, or VDD, e.g., power supply voltage reference, of integrated circuit power supply lines. The power grid wires may be formed of conductive materials, such as copper, aluminum, cobalt, tungsten, metal silicides, highly conductive tantalum nitride, any suitable conductive materials, and/or combinations thereof.

The integrated circuit chip 200 further includes one or more via towers 230 configured to provide electrical connection for power supply lines. The number and distribution of the via towers 230 may vary according to the circuit design. In some embodiments, the via towers 230 may be disposed in a seal ring region surrounding the semiconductor devices 204. In other embodiments, the via towers 230 may be distributed among semiconductor devices 204.

In some embodiments, each via tower 230 includes a front side stack 232 formed in the front side interconnect structures 222 and a middle stack 236 formed in the device layer 220. In some embodiments, the via tower 230 includes conductive features formed and stacked along a central axis 231. During operation, the via tower 230 is in connection with a power supply via the backside PDN 224 to provide an electrical communication path along the central axis 231.

As shown in FIG. 2A, the front side stack 232 include conductive plates 252 and via bars 254 alternatively formed in the IMD layers 210. Particularly, the front side stack 232 includes multiple pairs of conductive plate 252m and via bar 254m formed in the IMD layer 210m. The conductive plate 252m and the via bar 254m are fabricated simultaneously with the conductive lines 212m and vias 214m in the corresponding IMD layers 210m. Particularly, the conductive plates 252m and the conductive lines 212m are aligned on the same vertical level along the z-direction and the via bars 254m and the conductive vias 214m are aligned on the same vertical level along the z-direction. In some embodiments, the conductive plate 252m is larger than the via bar 254m to suitable for the damascene process used to fabricate the corresponding conductive lines 212m and conductive vias 214m.

FIG. 2B is a partial cross-sectional plan view the integrated circuit chip 200 along the line 2B-2B of FIG. 2A. As shown in FIG. 2A, the conductive plate 252m has a rectangular shape. The conductive plates 252m have a width W₂₅₂ long the x-direction and a length L₂₅₂ along the y-direction. In some embodiments, the width W₂₅₂ is in a range between about 0.1 micron and about 500 microns, and the length L₂₅₂ is in a range between about 0.1 micron and about 500 microns. The via bars 254m has a rectangular shape. The via bars 254m have a width W₂₅₄ long the x-direction and a length L₂₅₄ along the y-direction. In some embodiments, the width W₂₅₄ is in a range between about 0.008 micron and about 3 microns, and the length L₂₅₄ is in a range between about 0.1 micron and about 500 microns.

Even though only one via bar 254 is shown in FIG. 2B, two or more via bars 254 may be included to connect between conductive plates 252 between neighboring layers. For example, depending on location of the IMD layers and lithography technology used in fabrication, two or more via bars 254 may be arranged along y-direction between the conductive plates 252.

Even though the conductive plates 252m is shown having a rectangular shape, the conductive plates 252m may be any suitable shape or combinations of shapes according to the circuit layout. For example, the conductive plates 252m may be circular, triangular, oval, hexagonal, or any suitable shapes.

As shown in FIG. 2A, each pair of the conductive plates 252m and via bars 254m has a T-shaped cross-section. A height of the T-shaped cross-section corresponds to the thickness Tm of the corresponding IMD layer 210m. In some embodiment, the height of the pair of conductive plates 252m and via bars 254m is in a range between about 0.01 μm and about 6 μm. The height of the conductive plates 252 and the via bar 254 increases from the bottom most IMD layer 210₁ to the topmost IMD layer 210m.

The conductive plates 252 and via bars 254 are formed at the same time and with the same materials as the conductive lines 212 and conductive vias 214 in the corresponding IMD layers 210. For example, the conductive plates 252 and bia bars 254 may each include an electrically conductive material, such as Cu, Co, Ru, Mo, Cr, W, Mn, Rh, Ir, Ni, Pd, Pt, Ag, Au, Al, alloys thereof, or other suitable material. The conductive plates 252 and via bars 254 may be formed by physical vapor deposition (PVD), CVD, ALD, or other suitable process.

The middle stack 234 may include one or more layers of conductive plates and/or via bars formed through the device layer 220. In some embodiments, the middle stack 234 includes a via bar 262 and a conductive plate 264. The via bar 262 may be formed through device layer 220 and in contact with the bottom most conductive plate 252 of the front side stack 232. The conductive plate 264 is disposed below the device layer 220 and connected to the via bar 264. In some embodiments, the conductive plate 264 and the via bar 262 may be formed together during the back side process. In some embodiments, the via bar 262 may have a rectangular shape similar to the via bars 254. The conductive plate 264 may have a rectangular shape similar to the conductive plate 264. In some embodiments, the via bar 262 and the conductive plate 264 may be formed from a conductive material, such as Cu, Co, Ru, Mo, Cr, W, Mn, Rh, Ir, Ni, Pd, Pt, Ag, Au, Al, alloys thereof, or other suitable material. The via bar 262 and the conductive plate 264 may be formed by physical vapor deposition (PVD), CVD, ALD, or other suitable process.

In some embodiments, the via tower 230 may include a barrier layer and/or a liner around the conductive features of the via tower 230, such as the via bars 262, 254 and the conductive plates 252, 264. FIG. 2C is a schematical partial enlarged view of the via tower 230 in rectangular area 2C of FIG. 2A. FIG. 2C shows that a barrier layer 256 and a liner layer 258 disposed between the conductive features and the surrounding dielectric layer.

The barrier layer 256 may be formed of Ta, TaN, Ti, Co, Ru, Nb, W, AL, Mo, Ir., and combinations thereof and/or the like. The barrier layer 256 may be formed using suitable fabrication techniques such as ALD, PECVD, plasma enhanced physical vapor deposition (PEPVD) and/or the like. In some embodiments, the barrier layer 256 may be formed to a thickness in a range from about 10 angstroms to about 100 angstroms.

The liner layer 258 may be formed of suitable dielectric materials such as TEOS, silicon nitride, oxide, silicon oxynitride, low-K dielectric materials, high-K dielectric materials and/or the like. The liner layer 258 may be formed using suitable fabrication processes such as a PECVD process, although other suitable processes, such as PVD, a thermal process and/or the like, may alternatively be used. In some embodiments, the liner layer 258 may be formed to a thickness in a range from about 10 angstroms to about 100 angstroms.

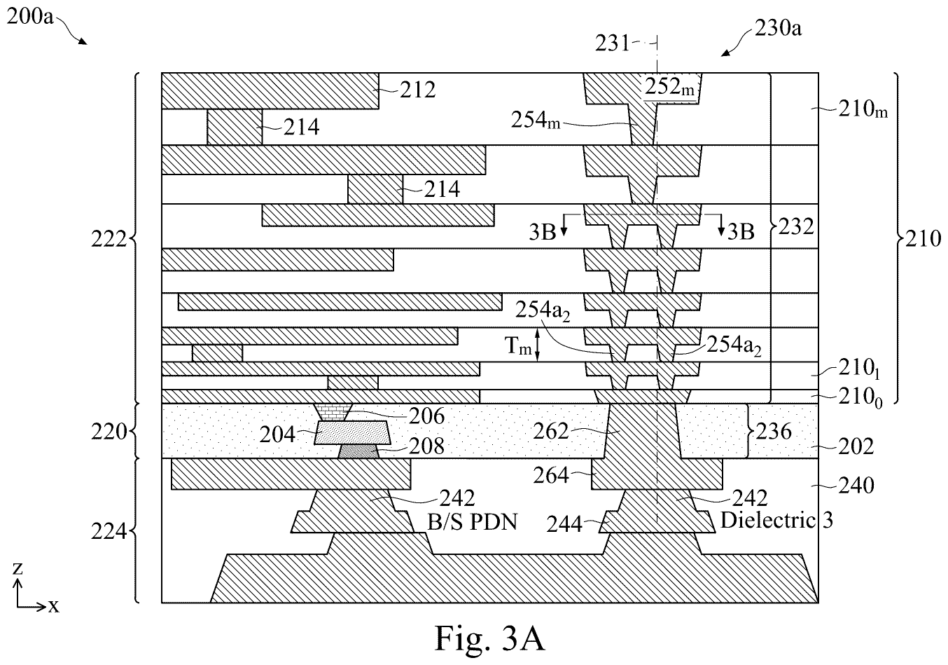

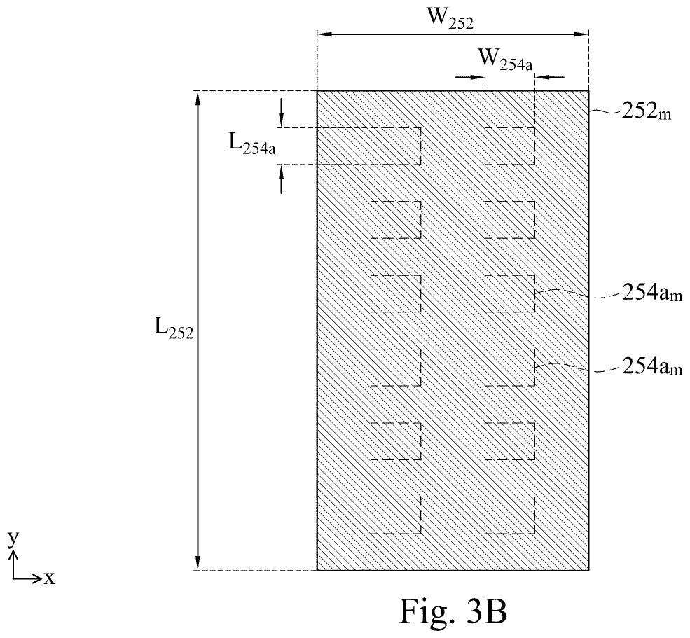

FIG. 3A is a schematical cross-sectional view of an integrated circuit chip 200a according to embodiments of the present disclosure. The integrated circuit chip 200a is similar to the integrated circuit chip 200 except that the integrated circuit chip 200a includes a via tower 230a stacked by layers of conductive plates 252a and arrays of vias 254a. FIG. 3B is a schematic top view of the integrated circuit chip 200a along the line 3B-3B in FIG. 3A. FIG. 3B schematically showing details of an array of vias 254a according to embodiments of the present disclosure.

As shown in FIGS. 3A-3B, an array of the conductive vias 254a are formed in the IMD layers 210m in connection with the conductive plates 252. The conductive vias 254a may be arranged in an array with spacing suitable for the size and arrangement of conductive vias 214 in the interconnect structure 222 according to design rules. The conductive via 254 may have a width W₂₅₄ₐ long the x-direction and a length L₂₅₄ₐ along the y-direction, or a diameter R₂₅₄ₐ. Depending on the location of the conductive vias 254 in the IMD layer 210m, the width W₂₅₄ₐ. Length L₂₅₄ₐ, or the diameter R₂₅₄ₐ is in a range between about 0.008 micron and about 3 microns.

Depending on the location of the IMD layers 210m, the number and dimension of the conductive vias 254a in each array may be different. In some embodiments, arrays of the conductive vias 254ma in different IMD layers 210m may have different diameters and numbers, but substantially the same cumulative cross-sectional areas. For example, the conductive vias 254 at a lower level IMD layer 210m, i.e. a level close to the device layer 220, may have a smaller diameter but arranged in a greater number, while the conductive vias 254 at a higher level IMD layer 210m, i.e. a level far away to the device layer 220, may have a larger diameter but arranged in a smaller number,

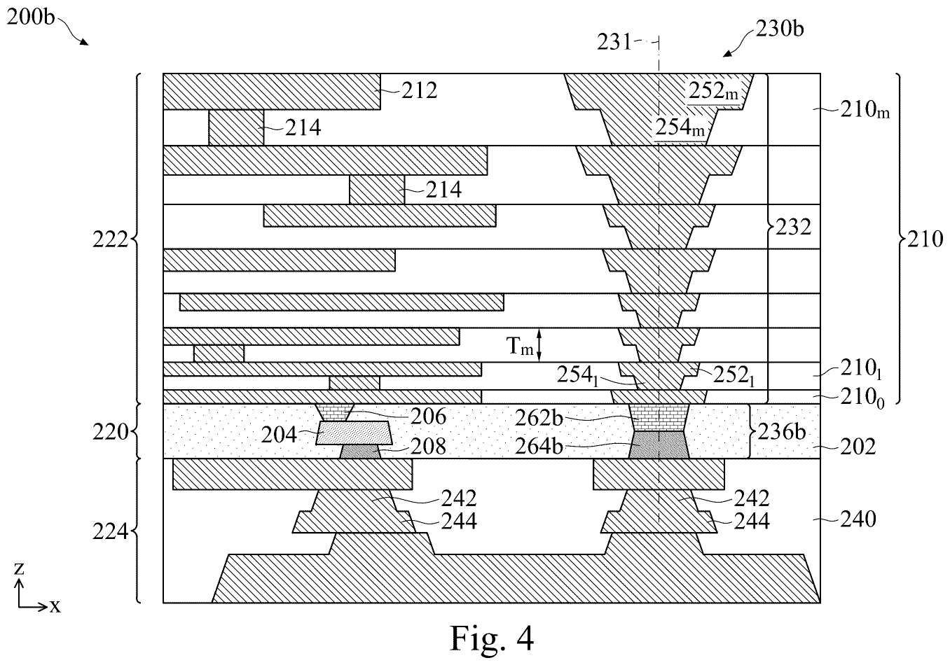

FIG. 4 is a schematical cross-sectional view of an integrated circuit chip 200b according to embodiments of the present disclosure. The integrated circuit chip 200b is similar to the integrated circuit chip 200 except that the integrated circuit chip 200b includes a via tower 230b having a middle stack 236b formed during front-end-of-line (FEOL) and middle-end-of-line (MEOL) processes instead of the conductive via formed during backside back-end-of-line (BEOL) process as the integrated circuit chip 200b.

In some embodiments, the middle stack 236b of the via tower 230b includes a front side via bar 262b and a backside via bar 264b formed along the central axis 231. The front side via bar 262b is formed during the FEOL/MEOL process performed on the front side, for example simultaneously with the front side contact features 206 in the device layer 220. The front side via bar 262b may be formed from the same material as the front side contact features 206. In some embodiment, the front side via bar 262b may be formed from one or more conductive materials, such as tungsten, cobalt, or other suitable materials for the front side contact features 206. After formation of the front side via bar 262b, the front side stack 232 are formed thereon in contact with the front side via bar 262b.

The back side via bar 264b is formed during the FEOL/MEOL process performed on the back side, for example simultaneously with the back side contact features 208 in the device layer 220. The backside via bar 264b may be formed from the same material as the back side contact features 208. In some embodiment, the back side via bar 264b may be formed from one or more conductive materials, such as tungsten, cobalt, or other suitable materials for the back side contact features 208. The back side via bar 264b is in contact with the front side via bar 262b forming an electrical connection through the device layer 220. After formation of the back side via bar 264b, the backside PDN 224 is then formed in contact with the back side via bar 264b to connect the via tower 230b with a power supply.

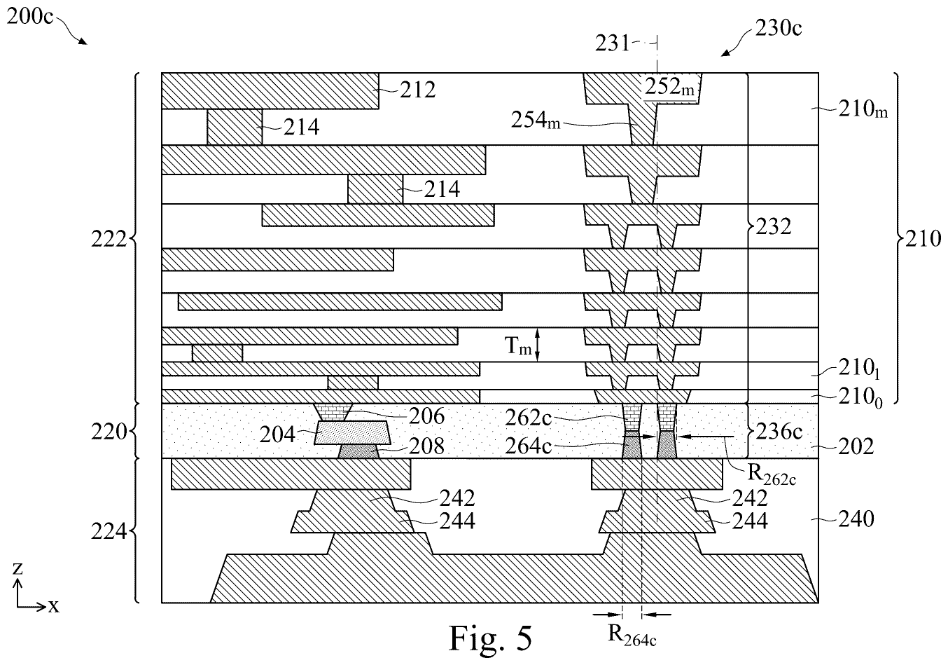

FIG. 5 is a schematical cross-sectional view of an integrated circuit chip 200c according to embodiments of the present disclosure. The integrated circuit chip 200c is similar to the integrated circuit chip 200a and integrated circuit chip 200b except that the integrated circuit chip 200c includes a via tower 230c having arrays of vias through the front side interconnect structure 222 and the device layer 220.

The via tower 230c includes a front side stack 232c and a middle stack 236c. The front side stack 232c includes layers of conductive plates 252c and arrays of vias 254c. In some embodiments, the front side stack 232c is substantially similar to the front side stack 232a shown in FIGS. 3A-3C above.

In some embodiments, the middle stack 236c of the via tower 230c includes an array of front side vias 262c and an array of back side vias 264c. The array of front side vias 262c is formed during the FEOL/MEOL process performed on the front side, for example simultaneously with the front side contact features 206 in the device layer 220. The array of front side vias 262c may be formed from the same material as the front side contact features 206.

The dimension and number of the front side vias 262c may be selected according to the dimension and density of the front side contact features 206. The array of front side vias 262c may be arranged in an array with spacing suitable for the size and arrangement of the front side contact features 206 according to design rules. The front side vias 262c may have a diameter R_{262c} in a range between about 0.005 micron and about 0.05 micron. In some embodiment, the array of front side vias 262c may be formed from one or more conductive materials, such as tungsten, cobalt, or other suitable materials for the front side contact features 206. After formation of the array of front side vias 262c, the front side stack 232 are formed thereon in contact with the array of front side vias 262c.

The array of back side vias 264c is formed during the FEOL/MEOL process performed on the back side, for example simultaneously with the back side contact features 208 in the device layer 220. array of back side vias 264c may be formed from the same material as the back side contact features 208. In some embodiment, the array of back side vias 264c may be formed from one or more conductive materials, such as tungsten, cobalt, or other suitable materials for the back side contact features 208.

The dimension and number of the back side vias 264c may be selected according to the dimension and density of the back side contact features 208. The array of back side vias 264c may be arranged in an array with spacing suitable for the size and arrangement of the back side contact features 208 according to design rules. The back side vias 264c may have a diameter R_{264c} in a range between about 0.005 micron and about 0.05 micron. The array of back side vias 264c is aligned with the array of front side vias 262c forming an array of parallel electrical connections through the device layer 220. After formation of the array of back side vias 264c, the backside PDN 224 is then formed in contact with the array of back side vias 264c to connect the via tower 230c with a power supply.

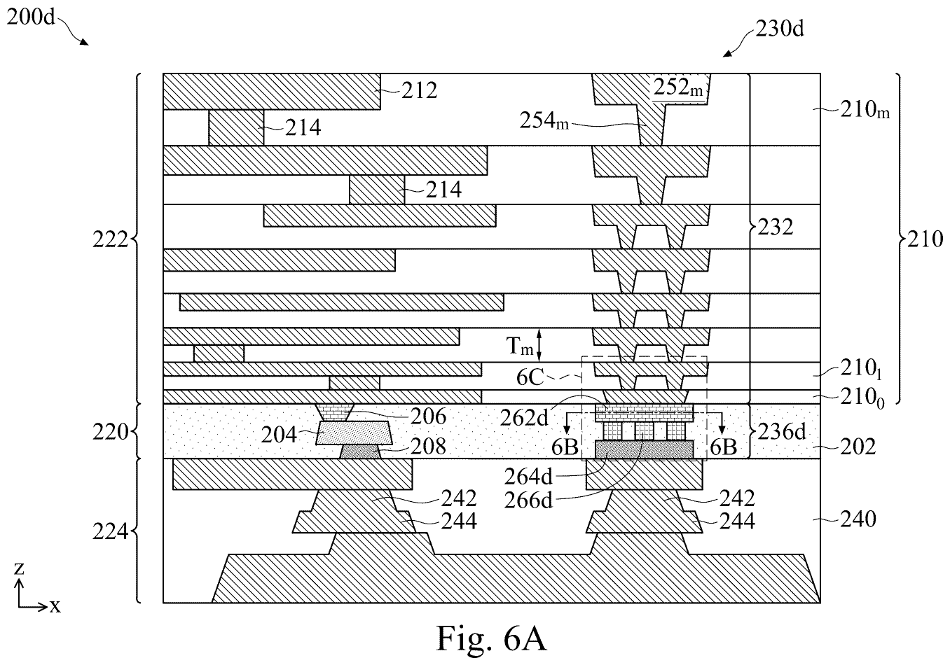

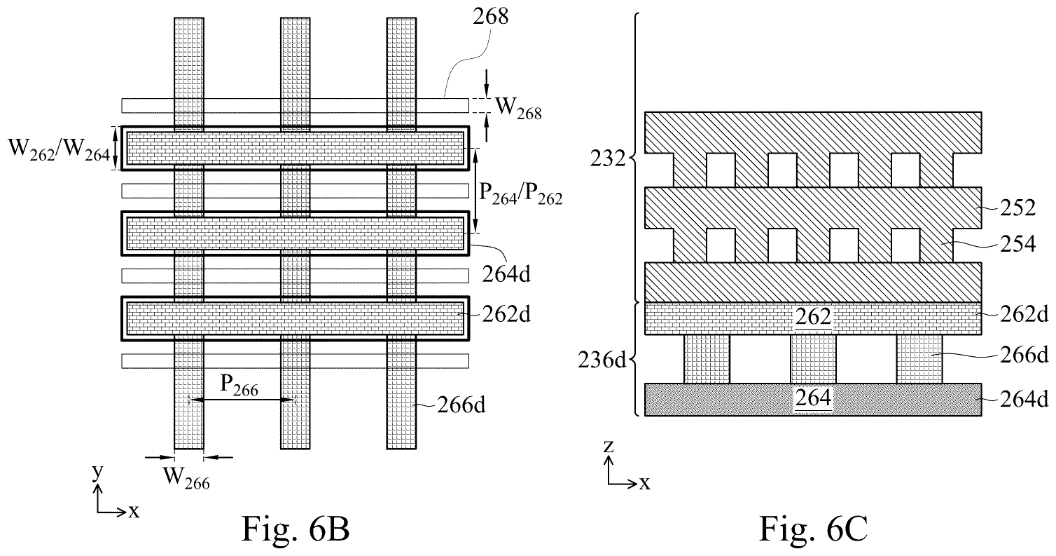

FIG. 6A is a schematical cross-sectional view of an integrated circuit chip 200d according to embodiments of the present disclosure. The integrated circuit chip 200d is similar to the integrated circuit chip 200c except that the integrated circuit chip 200d includes a via tower 230d having a via network 236d formed through the device layer 220. FIG. 6B is a schematic partial top view of the integrated circuit chip 200d along the line 6B-6B of FIG. 6A. FIG. 6B shows a top view of the via network 236d. FIG. 6C is a partial enlarged cross-sectional view of the integrated circuit chip 200d in a rectangular area 6C of FIG. 6A. FIG. 6C shows vertical arrangement of the via network 236d.

The via network 236d may include front side via bars 262d, back side via bars 264d and middle level via bars 266d. In some embodiments, the via network 236 includes layers of via bars integrated with the layout of the semiconductor devices 204. For example, the front side via bars 262d may be formed at the same level of gate contacts to transistors in the semiconductor devices 204, the middle level via bars 266d may be formed at the same level of front side source/drain contacts to the transistors in the semiconductor devices 204, and the back side via bars 264d are formed at the same level back side source/drain contact of the transistors in the semiconductor devices 204.

The front side via bars 262d are in contact with the front side stack 232 of the via tower 230d. The back side via bars 264d are in contact with the backside PDN 224. In some embodiments, the front side via bars 262d and the back side via bars 264d may include one or more conductive lines along a first direction, such as the x-direction, while the middle level via bars 266d include one or more conductive lines formed along a second direction perpendicular to the first direction, such as the y-direction.

In some embodiments, the pitches of the via network 236d may be selected according to the pitches of the semiconductor devices 204 in the device layer 220, therefore, complying with design rules and also allowing the via tower 230d to be formed within device regions of the integrated circuit chip 200d.

In some embodiments, as shown in FIG. 6B, the front side via bars 262d and the back side via bars 264d have the same pitch P₂₆₄/P₂₆₂ along the y-direction so that front side via bars 262d and the back side via bars 264d are aligned with each other in the y-direction. In some embodiments, the front side via bars 262d and the back side via bars 264d may be arranged parallel to semiconductor fins 268, along which the semiconductor devices 204 are formed. In some embodiments, the pitch P₂₆₄/P₂₆₂ may be the same as the pitch of the semiconductor fins 268 along the y-direction. In some embodiments, the pitch P₂₆₄/P₂₆₂ may be in a range between about 50 nm and 300 nm. In some embodiments, the front side via bars 262d and the back side via bars 264d may have a width W₂₆₄/W₂₆₂ along the y-direction in a range between about 10 nm and 250 nm. In some embodiments, the semiconductor fins 268 may be optionally disposed between the front side via bars 262d and the back side via bars 264d. In some embodiments, the semiconductor fins 268 may have a width W₂₆₈ along the y-direction in a range between about 2 nm and 100 nm.

The middle level via bars 266d are formed perpendicular to the front side via bars 262d and the back side via bars 264d. The middle level via bars 266d are arranged in a pitch P₂₆₆ along the x-direction. In some embodiments, the pitch P₂₆₆ may be similar to the pitch of gate of the semiconductor devices 204. In some embodiments, the pitch P₂₆₆ may be in a range between about 20 nm and 300 nm. In some embodiments, the middle level via bars 266d may have a width W₂₆₆ along the x-direction in a range between about 10 nm and 250 nm.

The via network 236d may be fabricated during existing fabrication processes without adding any extra steps. In some embodiments, the front side via bars 262d and the middle level via bars 266d are formed during the FEOL/MEOL process performed on the front side, for example simultaneously with the front side contact features 206 in the device layer 220. The front side via bars 262d and the middle level via bars 266d may be formed from the same material as the front side contact features 206. The back side via bars 264d are formed during the FEOL/MEOL process performed on the back side, for example simultaneously with the back side contact features 208 in the device layer 220. The back side via bars 264d may be formed from the same material as the back side contact features 208 in the device layer 220.

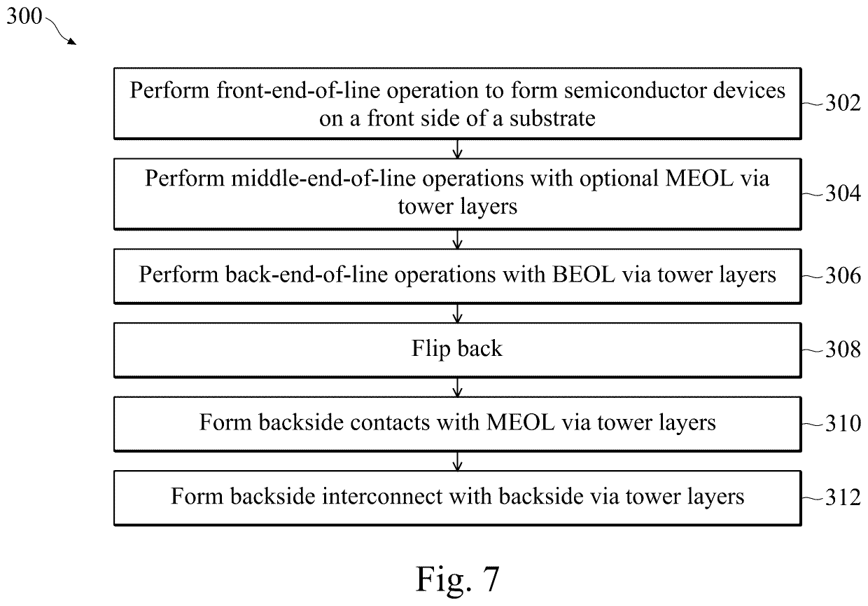

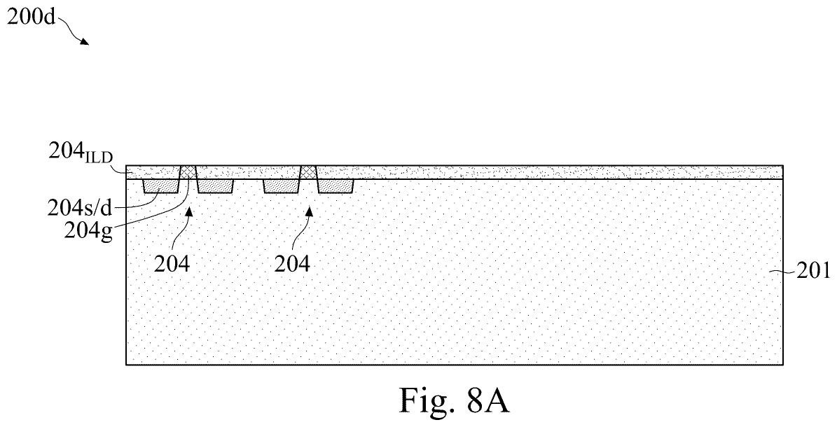

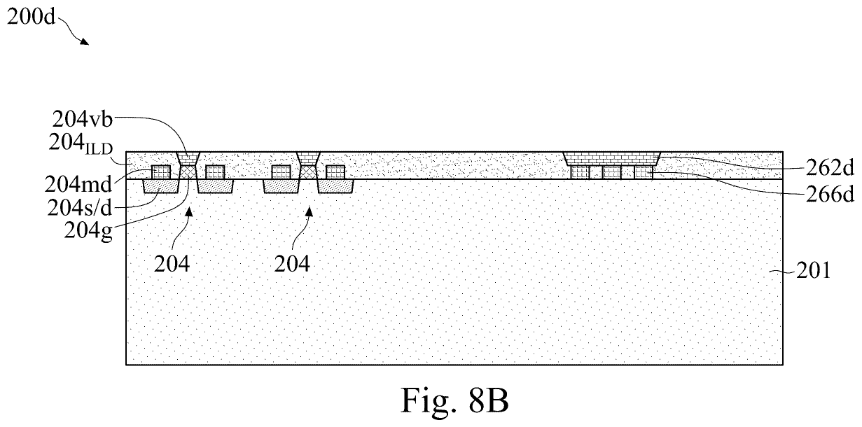

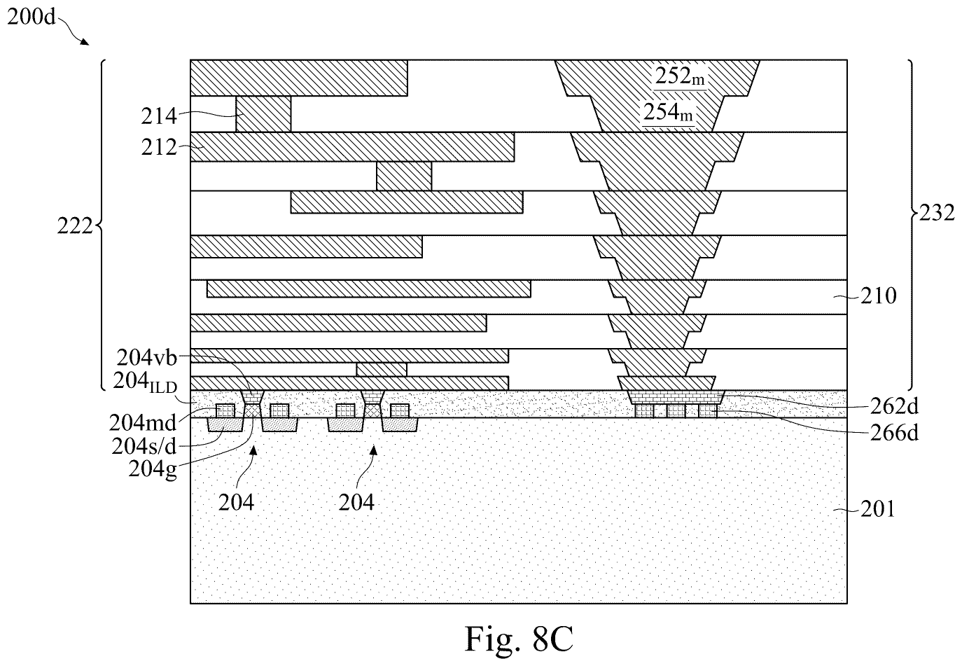

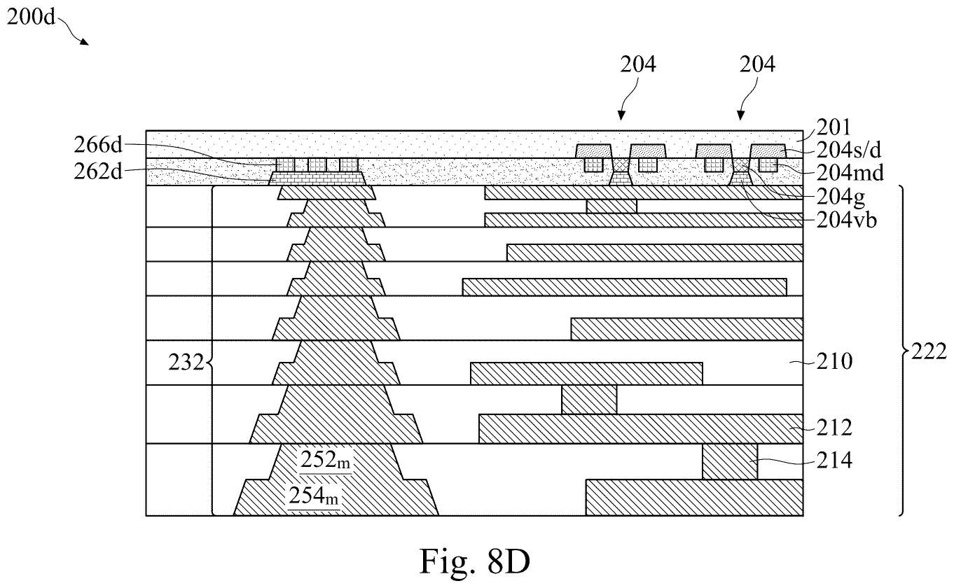

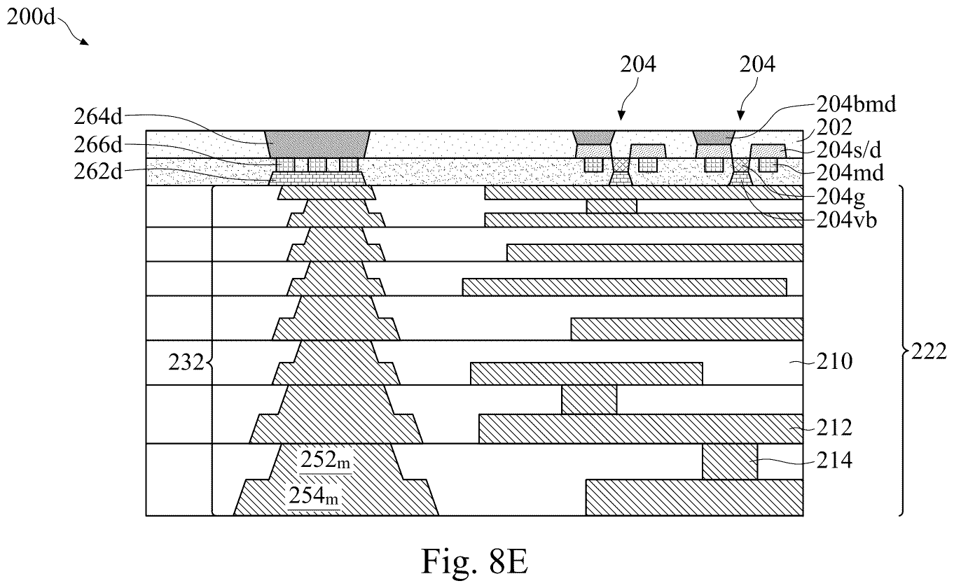

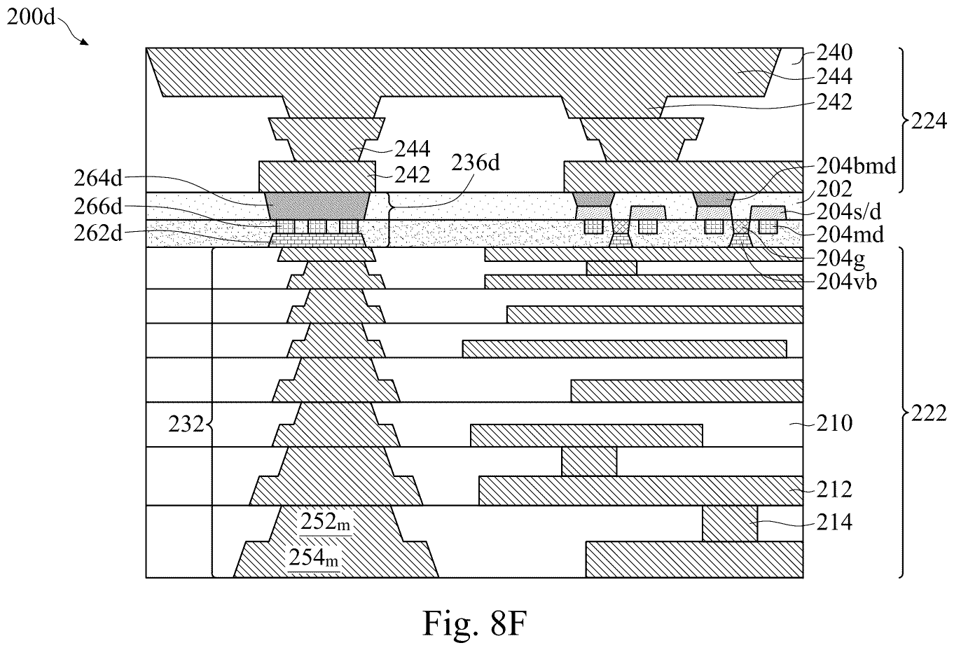

FIG. 7 is a flow diagram of a method 300 forming of integrated circuit chips having via towers according to embodiments of the present disclosure. Particularly, the method 300 forms integrated circuits chips having via towers used in 3DIC packaging. The method 300 may be used to fabricate the integrated circuit chips 200, 200a, 200b, 200c, 200d, and the bottom chip layer 102 described above. FIGS. 8A-8F schematically demonstrate various processing stages during fabrication of integrated circuit chip according to embodiments of the present disclosure.

In operation 302 of the method 300, a FEOL process sequence is performed to fabricate a plurality of semiconductor devices 204 on a front side of a semiconductor substrate 201, as shown in FIG. 8A. FIG. 8A is a schematic perspective view of the integrated circuit chip 200d after operation 302.

The semiconductor substrate 201 is provided to form the integrated circuit chip 200d thereon. The semiconductor substrate 201 may include a single crystalline semiconductor material such as, but not limited to Si, Ge, SiGe, GaAs, InSb, GaP, GaSb, InAlAs, InGaAs, GaSbP, GaAsSb, and InP. The semiconductor substrate 201 may include various doping configurations depending on circuit design.

In some embodiments, a plurality of semiconductor devices 204 are formed on and from the semiconductor substrate 201. The semiconductor devices 204 may be transistors, diodes, imaging sensors, resistors, capacitors, inductors, memory cells, combinations thereof, and/or other suitable devices. In some embodiments, the semiconductor devices 204 may be transistors, such as FinFET and nanostructure FET having one or more channels wrapped around by a gate electrode layer.

In some embodiments, the semiconductor devices 204 may include be transistors having source/drain regions 204s/d and gate structures 204g formed over channel regions between the source/drain regions 204s/d. In some embodiments, an ILD layer 204ILD are formed over the transistors.

In operation 304, a MEOL process sequence is performed to form contact features to the transistors, and optionally, layers for a via tower according to embodiments of the present disclosure, as shown in FIG. 8B.

Depending on circuit design, contact features, such as conductive vias, are formed through the ILD layer 204ILD to provide electrical communications to the transistors. For example, front side source/drain contacts 204md and gate contacts 204vb may be formed during operation 304. Optionally, layers for a via tower according to the present disclosure may be formed simultaneously with the front side source/drain contacts 204md and the gate contacts 204vb.

In some embodiments, one or more middle level via bars 266d may be patterned and formed with the front side source/drain contacts 204md, and one or more front side via bars 262d may be patterned and formed with the gate contacts 204vb. Alternatively, the front side via 262b in FIG. 4 or the front side via bars 262c in FIG. 5 may be fabricated in operation 304.

In operation 306, a BEOL process sequence is performed to fabricate a front side interconnect structure 222 over the semiconductor devices 204 and layers of the via tower are formed in each IMD layer 210, as shown in FIG. 8C.

The front side interconnect structure 222 includes multiple IMD layers 210 having conductive lines 212 and conductive vias 214 embedded therein. The IMD layers 210 are formed layer by layer by suitable processes. The conductive plates 252 and via bars 254 or vias 254a may be formed in each IMD layer 210 with the conductive lines 212 and conductive vias 214. The conductive layers 252 and the vias 254 may be incorporated with pattern layouts of the IMD layers without additional cost. After operation 306, the top stack 232 and middle stack 236 of the via tower 230 are formed.

In operation 308 of the method 300, the semiconductor substrate 201 is flipped over and a back side thinning process is performed, as shown in FIG. 8D. In some embodiments, a carrier wafer (not shown) may be bond to a front side of the integrated circuit chip 200d, and the semiconductor substrate 201 is flipped over so that the backside of the semiconductor substrate 201, is facing up for backside processing. A backside grinding is performed thin down the semiconductor substrate 201. For example, the back side grinding, such as a CMP process, may be performed to expose alignment features, such as buried source/drain features, for formation of back side contacts.

In operation 310 of the method 300, back side contact features, such as backside source/drain contact 204bmd are formed, and optionally MEOL layers for the via tower according to embodiments of the present disclosure, as shown FIG. 8E. In FIG. 8E, backside via bars 264d are added to layout of the backside source/drain contact 204bmd to be patterned and formed at the same process. Alternatively, other designs, such as backside via bars 264b in FIG. 4 and the back side vias 264c in FIG. 5.

In operation 312 of the method 300, backside interconnect structure 224 formed with a BEOL process, as shown in FIG. 8F. In some embodiments, the backside interconnect structure 224 may be a backside PDN configured to deliver electrical power to the semiconductor devices 204 and to the via tower 230 formed through the device layer 220 and the front side interconnect structures 222. In other embodiments, alternatively stacked conductive plates and conductive vias may be formed in the backside interconnect structure 224 as part of the via tower 230.

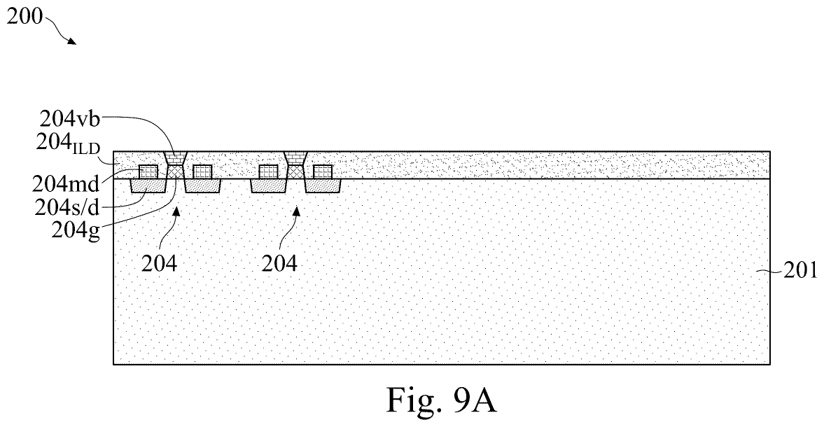

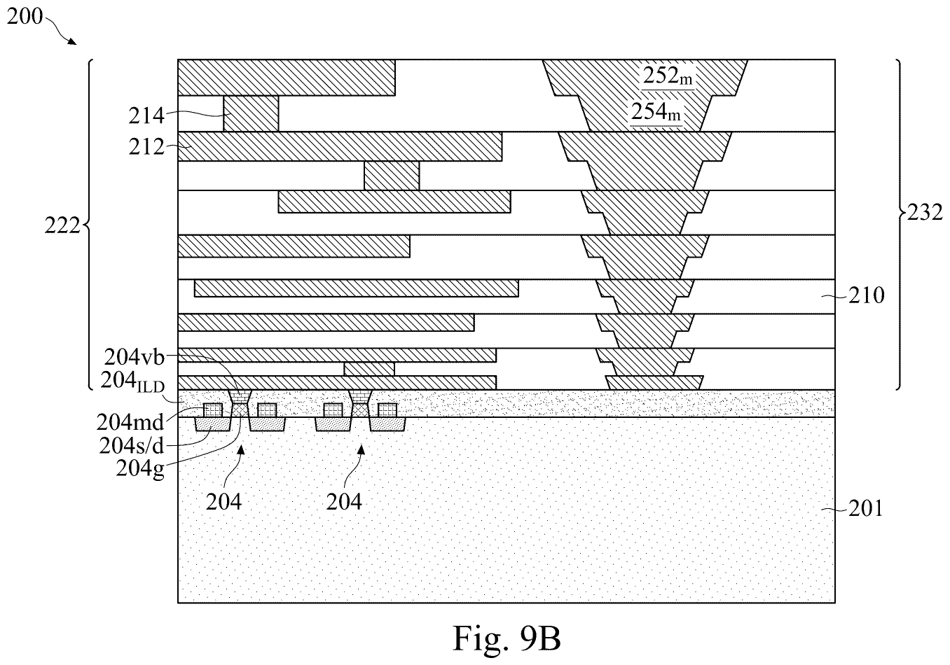

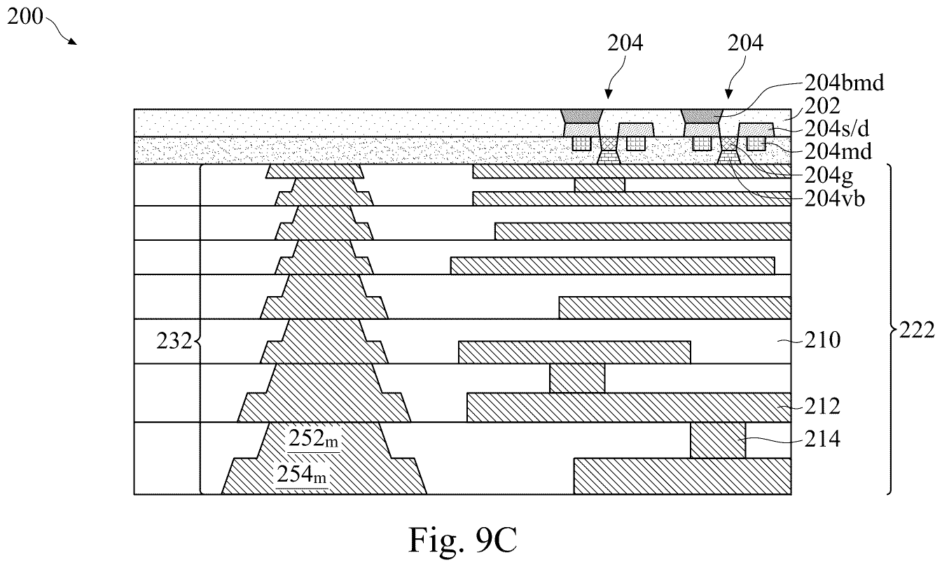

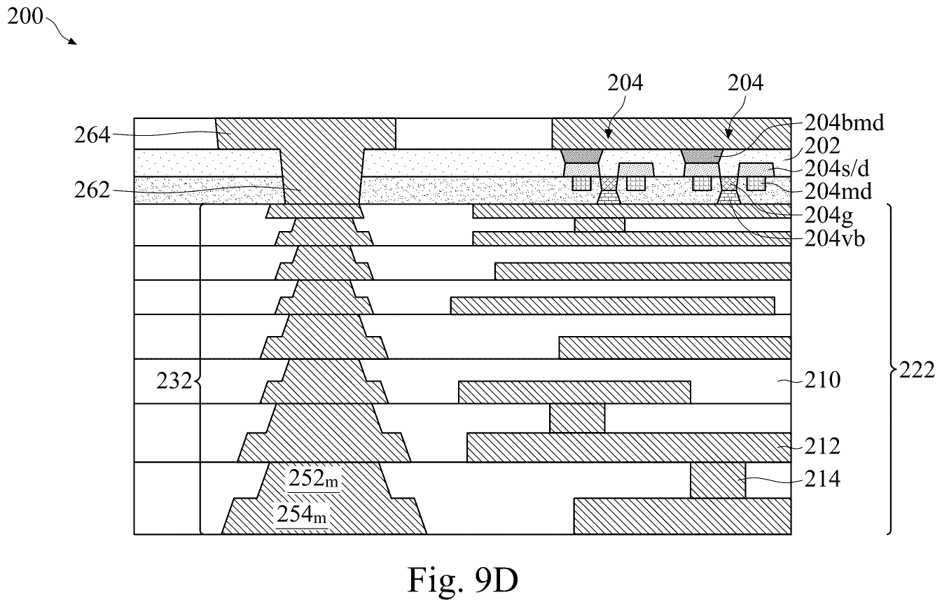

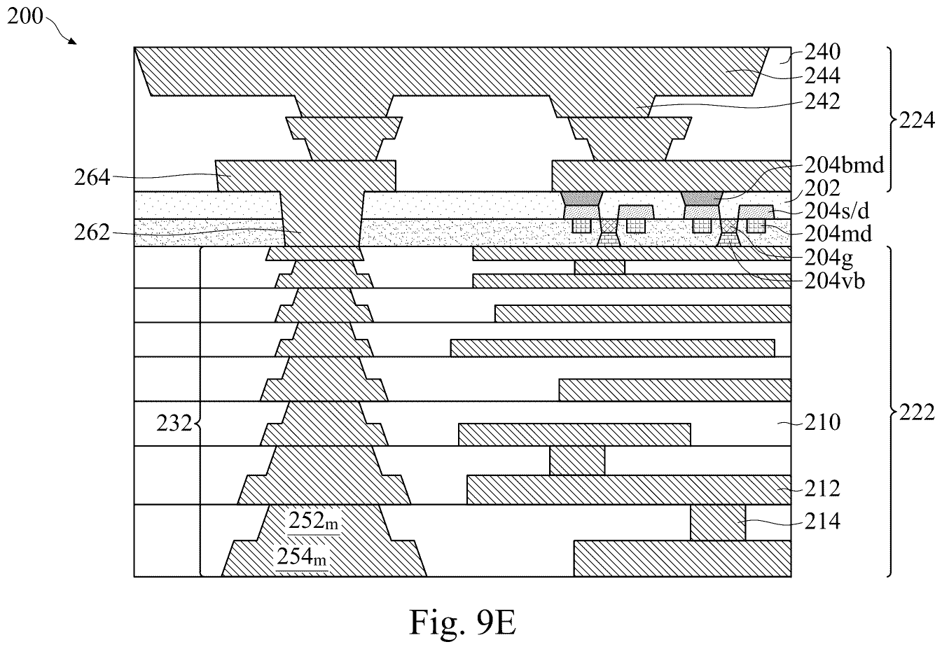

FIGS. 9A-9E schematically demonstrate various processing stages during fabrication of the integrated circuit chip 200 according to embodiments of the present disclosure. Particularly, the integrated circuit chip 200 may be fabricated using the method 300.

FIG. 9A schematically illustrates the integrated circuit chip 200 after operation 304. As shown in FIG. 9A, the optional MEOL layers for the via tower area in operation 304 are omitted. FIG. 9B schematically illustrates the integrated circuit chip 200 after operation 308. FIG. 9C schematically illustrates the integrated circuit chip 200 after operation 310. As shown in FIG. 9C, the MEOL tower layers are omitted in performing operation 310.

In operation 312, an opening is formed through the device layer 220 from the backside of the semiconductor substrate 201 to expose the front side stack 232. The opening is then filled to form the conductive via 262 and the conductive plate 264, as shown in FIG. 9D. After formation of the conductive via 262 and the conductive plate 264, operation 312 continues to form the backside interconnect structure 224, as shown in FIG. 9E.

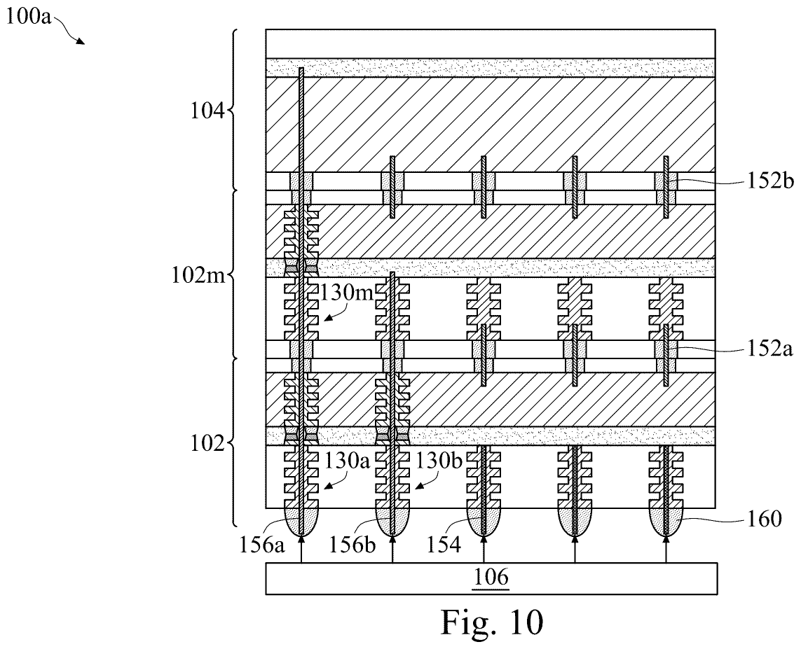

FIG. 10 a schematical cross-sectional view of a 3DIC structure 100a according to embodiments of the present disclosure. The 3DIC structure 100a is similar to the 3DIC structure 100 except that the 3DIC structure 100a includes a middle chip layer 102m disposed between the top chip layer 104 and the bottom chip layer 102. The bottom chip layer 102 and the middle chip layer 102m may include via towers for delivering electrical power according to the present disclosure. In some embodiments, the bottom chip layer 102 and the middle chip layer 102m may be selected from the integrated circuit chips 200, 200a, 200b, 200c, 200d described above. As shown in FIG. 10, the bottom chip layer 102 includes one or more via towers 130a, 130b, and the middle chip layer 102m includes one or more via tower 130m. The via towers 130a, 130b may be connected to provide power supply through the bottom chip layer 102 to chip layers stacked above.

The middle chip layer 102m is stacked on the bottom chip layer 102 forming electrical paths 152a therebetween. At least two electric paths 152a are connected to the via towers 130a and 130b in the bottom chip layer 102 to provide electrical power from to the middle chip layer 102m through the bottom chip layer 102. The top chip layer 104 is bonded to the middle chip layer 102m forming electrical paths 152b therebetween. At least one electric path 152b is connected to the via tower 130m for providing electrical power to the top chip layer 104 from the middle chip layer 102m. At least one via tower 130a in the bottom chip layer 102 is align with the via tower 130m in the middle chip layer 102m, forming electrical path 156a to supply electrical power to the top chip layer 104 through the bottom chip layer 102 and the middle chip layer 102m.

During operation, the power supply 106 is connected to the bottom chip layer 102 via bond pads 160. The bond pads 160 are in electrical connection with the via towers 130a and 130b. In some embodiments, the power supply 106 is connected to the device layer 120 of the bottom chip layer 102 via flow paths 154, which may include one or more bond pad 160 and conductive features in the backside interconnect structure of the bottom chip layer 102. The power supply 106 is supplied to the middle chip layer 102m via an electrical path 156b, which includes a bond pad 160, the via tower 130b and the electrical path 152a connected to the via tower 130b. The power supply 106 is supplied to the top chip layer 104 via the electrical path 156b, which includes a bond pad 160, the via tower 130a, the electrical path 152a connected to the via tower 130a, the via tower 130m, and the electric path 152b connected to the via tower 130m.

Embodiments of the present disclosure provide integrated circuit chips including via towers formed with stacks of conductive layers formed during fabrication of semiconductor devices and interconnect structures of the integrated circuit chips. The via towers may replace through silicon vias (TSVs). The via towers according to the present disclosure reduce cost of fabrication because the via towers are fabricated without additional processing sequences, such as process sequences for fabricating TSVs. The via towers may be integrated in the circuit layout to form a low resistance power rail, therefore, improving performance.

It will be understood that not all advantages have been necessarily discussed herein, no particular advantage is required for all embodiments or examples, and other embodiments or examples may offer different advantages.

Some embodiments of the present disclosure relate to a semiconductor package comprising a first integrated circuit chip layer, comprising: a device layer having a plurality of semiconductor devices; a first interconnect structure disposed over a first side of the device layer; a second interconnect structure disposed over a second side of the device layer; and a via tower configured to provide an electrical connection through the first interconnect structure, the device layer, and the second interconnect structure, wherein the via tower comprises a stack of conductors formed through the device layer and at least one of the first and second interconnect structures; and a second integrated circuit chip layer bonded the first integrated circuit chip layer, wherein the via tower is in electrical connection with the second integrated circuit chip via a bond pad feature.

Some embodiments of the present disclosure relate to an integrated circuit chip, comprising: a device layer having a plurality of semiconductor devices; a first interconnect structure disposed over a first side of the device layer; a second interconnect structure disposed over a second side of the device layer; and a via tower configured to provide an electrical connection through the first interconnect structure, the device layer, and the second interconnect structure, wherein the via tower comprises: a first stack of conductors disposed through the first interconnect structure; and a second stack of conductors disposed through the device layer, wherein the second stack of conductors is in contact with the first stack of conductors.

Some embodiments of the present disclosure relate to a method comprising forming a device layer comprising a plurality of semiconductor devices in and over a substrate; forming a first interconnect structure over a first side of the device layer, wherein the first interconnect structure comprises a plurality of intermetal dielectric (IMD) layers, and a first stack of conductors through the first interconnect structures and embedded in the plurality of IMD layers; forming a backside conductor in the device layer from a second side of the device layer, wherein the backside conductor is electrical connection with the first stack of conductors; and forming a second interconnect structure over the second side of the device layer, wherein the second interconnect structure includes an electrically conductive path to the backside conductor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first integrated circuit chip layer, comprising:
a device layer having a plurality of semiconductor devices;
a first interconnect structure disposed over a first side of the device layer;
a second interconnect structure disposed over a second side of the device layer; and
a via tower configured to provide an electrical connection through the first interconnect structure, the device layer, and the second interconnect structure, wherein the via tower comprises a stack of conductors formed through the device layer and at least one of the first and second interconnect structures; and
a second integrated circuit chip layer bonded the first integrated circuit chip layer, wherein the via tower is in electrical connection with the second integrated circuit chip via a bond pad feature.

2. The semiconductor package of claim 1, wherein the via tower comprises
a first stack of conductors disposed through the first interconnect structure; and
a second stack of conductors disposed through the device layer, wherein the second stack of conductors is in contact with the first stack of conductors, and the bond pad feature is in contact with the first stack of conductors.

3. The semiconductor package of claim 2, wherein the second interconnect structure includes a backside power delivering network (PDN).

4. The semiconductor package of claim 2, wherein the via tower further comprises:
a third stack of conductors disposed through the second interconnect structure, wherein the third stack of conductors is in contact with the second stack of conductors.

5. The semiconductor package of claim 2, wherein the second stack of conductors comprises:
a front side conductor disposed in the first side of the device layer; and
a backside conductor disposed in the second side of the device layer.

6. The semiconductor package of claim 5, wherein the second stack of conductors comprises:
a middle conductor disposed between the front side conductor and the backside conductor, wherein the front side conductor and the backside conductor are conductive lines along a first direction and the middle conductor is a conductive line along a second direction.

7. An integrated circuit chip, comprising:
a device layer having a plurality of semiconductor devices;
a first interconnect structure disposed over a first side of the device layer;
a second interconnect structure disposed over a second side of the device layer; and
a via tower configured to provide an electrical connection through the first interconnect structure, the device layer, and the second interconnect structure, wherein the via tower comprises:
a first stack of conductors disposed through the first interconnect structure; and
a second stack of conductors disposed through the device layer, wherein the second stack of conductors is in contact with the first stack of conductors.

8. The integrated circuit chip of claim 7, wherein the first interconnect structure comprises a plurality of intermetal dielectric (IMD) layers, and the first stack of conductors comprises a plurality of embedded conductors in the plurality of IMD layer.

9. The integrated circuit chip of claim 8, wherein each of the embedded conductors comprises:
a conductive plate; and
a via bar in contact with the conductive plate.

10. The integrated circuit chip of claim 8, wherein each of the embedded conductors comprises:
a conductive plate; and
an array of vias in contact with the conductive plate.

11. The integrated circuit chip of claim 7, wherein the via tower further comprises:
a third stack of conductors disposed through the second interconnect structure, wherein the third stack of conductors is in contact with the second stack of conductors.

12. The integrated circuit chip of claim 7, wherein the second interconnect structure includes a backside power delivering network (PDN).

13. The integrated circuit chip of claim 7, wherein the second stack comprises:
a front side conductor disposed in the first side of the device layer; and
a backside conductor disposed in the second side of the device layer.

14. The integrated circuit chip of claim 13, wherein the second stack further comprises:
a middle conductor disposed between the front side conductor and the backside conductor, wherein the front side conductor and the backside conductor are conductive lines along a first direction and the middle conductor is a conductive line along a second direction.

15. A method for forming an integrated circuit chip, comprises:
forming a device layer comprising a plurality of semiconductor devices in and over a substrate;
forming a first interconnect structure over a first side of the device layer, wherein the first interconnect structure comprises a plurality of intermetal dielectric (IMD) layers, and a first stack of conductors through the first interconnect structures and embedded in the plurality of IMD layers;
forming a backside conductor in the device layer from a second side of the device layer, wherein the backside conductor is electrical connection with the first stack of conductors; and
forming a second interconnect structure over the second side of the device layer, wherein the second interconnect structure includes an electrically conductive path to the backside conductor.

16. The method of claim 15, further comprising:
forming a front side conductor in the device layer from the first side of the device layer, wherein the first stack of conductors is in contact with the front side conductor.

17. The method of claim 16, wherein the backside conductor is formed over and in contact with the front side conductor.

18. The method of claim 16, further comprising:
forming a middle conductor in the device layer prior to forming the front side conductor, wherein the middle conductor is a conductive line along a first direction, the front side conductor and the backside conductor are conductive lines along a second direction, and the middle conductor is in contact with the front side conductor and the backside conductor.

19. The method of claim 17, wherein forming the middle conductor is performed simultaneously with forming source/drain contacts to the plurality of semiconductor devices and forming the front side conductor is performed simultaneously with forming gate contacts to the plurality of semiconductor devices.

20. The method of claim 15, wherein the second interconnect structure includes a backside power delivering network (PDN).
